(19) United States
(12) Patent Application Publication
(10) Pub. No.: US 2025/0379072 A1
(43) Pub. Date: Dec. 11, 2025

(54) SUBSTRATE HEATING APPARATUS AND SUBSTRATE HEATING METHOD

(71) Applicant: Tokyo Electron Limited, Tokyo (JP)

(72) Inventor: Kensaku NARUSHIMA, Nirasaki City (JP)

(21) Appl. No.: 19/230,163

(22) Filed: Jun. 6, 2025

(30) Foreign Application Priority Data
Jun. 11, 2024 (JP) 2024-094253

(51) Int. Cl. H01L 21/67

(52) U.S. Cl. CPC H01L 21/67115; H01L 21/67109; H01L 21/67248

(57) ABSTRACT

A substrate heating apparatus includes an accommodation chamber configured to accommodate a substrate, a transparent window provided on a wall portion of the accommodation chamber to face the substrate, a heating light source configured to irradiate the substrate with an irradiation light via the transparent window and configured to heat the substrate, and a light-transmitting mask member provided between the transparent window and the substrate.

### CROSS-REFERENCE TO RELATED APPLICATION

This application is based upon and claims the benefit of priority from Japanese Patent Application No. 2024-094253, filed on Jun. 11, 2024, the entire contents of which are incorporated herein by reference.

### TECHNICAL FIELD

The present disclosure relates to a substrate heating apparatus and a substrate heating method.

### BACKGROUND

In recent years, as semiconductor device manufacturing processes have shifted toward lower temperatures, impurities such as unreacted by-products and residual gases may remain inside various films formed on the surface of a substrate, such as a wafer, on which semiconductor devices are formed. When these impurities are vaporized and are released from the films during various types of processing performed on the wafer, the quality of manufactured semiconductor devices may be affected. Therefore, in order to vaporize and release impurities remaining inside various films before performing various types of processing on the wafer, a technology for heating the wafer has been developed. For example, a technology for irradiating the wafer with LED light from a light irradiation unit to heat the wafer has been proposed (see, e.g., Patent Document 1).

### PRIOR ART DOCUMENTS

### Patent Documents

Patent Document 1: Japanese Laid-Open Publication No. 2023-117618

### SUMMARY

According to one embodiment of the present disclosure, there is provided a substrate heating apparatus including an accommodation chamber configured to accommodate a substrate, a transparent window provided on a wall portion of the accommodation chamber to face the substrate, a heating light source configured to irradiate the substrate with an irradiation light via the transparent window and configured to heat the substrate, and a light-transmitting mask member provided between the transparent window and the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating a configuration of a substrate processing system including a substrate heating apparatus according to an embodiment of the technique related to the present disclosure.

FIG. 2 is a cross-sectional view schematically illustrating a configuration of a load lock chamber in FIG. 1.

FIG. 3 is a diagram illustrating an LED light source in FIG. 2 as viewed from below.

FIGS. 4A and 4B are cross-sectional views schematically illustrating a configuration of a stage in FIG. 2.

FIGS. 5A to 5C are diagrams illustrating a configuration of a mask member in FIG. 2.

FIGS. 6A to 6C are cross-sectional views schematically illustrating a configuration of a mask member having a lens function.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings. Like reference numerals will be given to the substantially the same configurations throughout the drawings, and redundant description thereof will be omitted.

In the technology disclosed in Patent Document 1 above, a wafer is heated in a load lock chamber whose interior is switchable between a vacuum and atmospheric pressure. Specifically, the wafer is accommodated in the interior of the load lock chamber, and the interior of the load lock chamber is depressurized. Thereafter, LED light is emitted from an LED light source, provided outside the load lock chamber, toward the wafer through a transparent window provided to face the wafer. Then, the impurities vaporized and released from the heated wafer are discharged to the outside of the load lock chamber by an exhaust system of the load lock chamber.

However, before the impurities vaporized and released from the wafer are discharged outward of the load lock chamber, the impurities may reach and adhere to the transparent window. When the impurities adhere to the transparent window, the transmittance of the transparent window may be reduced, which reduces heating efficiency of the wafer by the LED light from the LED light source. To address this issue, in the technology according to the present disclosure, a light-transmitting mask member is provided between the transparent window and the wafer.

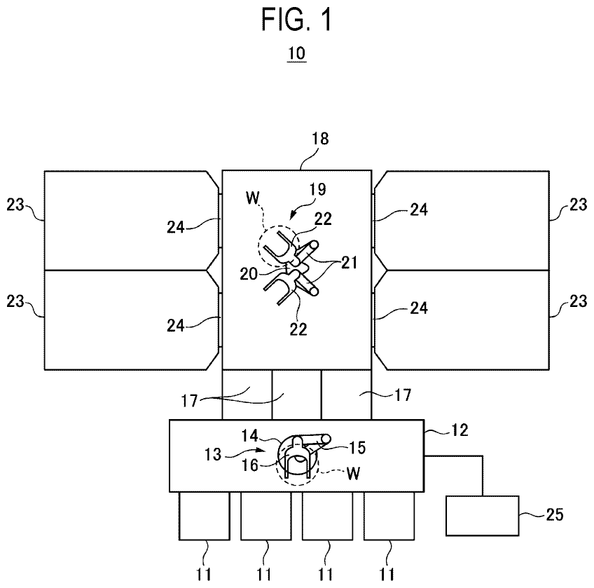

Hereinafter, one embodiment of the technology according to the present disclosure will be described with reference to the drawings. FIG. 1 is a plan view schematically illustrating a configuration of a substrate processing system 10 including a substrate heating apparatus according to the present embodiment.

In FIG. 1, the substrate processing system 10 includes four load ports 11. A FOUP (not illustrated), which is a container in which a plurality of wafers W (substrates) having, e.g., a diameter of φ300 mm, are accommodated, is attached to each of the four load ports 11. The load ports 11 are connected to a loader chamber 12, which is an atmospheric transfer chamber. The loader chamber 12 has a substantially rectangular parallelepiped shape. An interior of the loader chamber 12 is maintained in an atmospheric pressure atmosphere. Further, a transfer robot 13 (substrate transfer mechanism) is arranged in the interior of the loader chamber 12 to transfer the wafers W.

The transfer robot 13 includes a base 14, which is movable in the longitudinal direction of the loader chamber 12, an arm 15, which is rotatable and extendible on a horizontal plane relative to the base 14, and a pick 16, which is provided at a tip of the arm 15 to hold the wafers W. The transfer robot 13 loads and unloads the wafers W into and from each FOUP and each load lock chamber 17, which will be described later, by moving the base 14, and rotating and extending/contracting the arm 15. In addition, the arm 15 is configured to be movable in a vertical direction relative to the base 14.

Further, three load lock chambers 17 are arranged as substrate delivery chambers on a side opposite the load ports 11 via the loader chamber 12. Each of the load lock chambers 17 includes an exhaust system (not illustrated) configured to switch the interior of each of the load lock chambers 17 between a vacuum atmosphere and an atmospheric pressure atmosphere. The interior of each of the load lock chambers 17 is set to the atmospheric pressure atmosphere when it is in communication with the loader chamber 12, and is set to the vacuum atmosphere when it is in communication with a substrate transfer chamber 18, which will be described later. Each of the load lock chambers 17 functions as an intermediate transfer chamber for delivering the wafers W between the loader chamber 12 and the substrate transfer chamber 18. In the present embodiment, as will be described later, each of the load lock chambers 17 also functions as a substrate heating apparatus.

The substrate transfer chamber 18 is arranged on a side opposite the loader chamber 12 via the load lock chambers 17. The substrate transfer chamber 18 has a substantially rectangular parallelepiped shape. An interior of the substrate transfer chamber 18 is maintained in a vacuum atmosphere. Further, a transfer robot 19 is arranged in the interior of the substrate transfer chamber 18 to transfer the wafers W.

The transfer robot 19 includes a base 20, which is movable in a longitudinal direction of the substrate transfer chamber 18, an arm 21, which is rotatable and extendible on a horizontal plane relative to the base 20, and a pick 22, which is provided at a tip of the arm 21 to hold the wafers W. The transfer robot 19 loads and unloads the wafers W into and from each load lock chamber 17 and each substrate processing chamber 23 (to be described later), by moving the base 20 and rotating and extending/retracting the arm 21.

Four substrate processing chambers 23 are connected to the substrate transfer chamber 18 via gate valves 24. The gate valves 24 control communication between the respective substrate processing chambers 23 and the substrate transfer chamber 18. An interior of each substrate processing chamber 23 is maintained in a vacuum atmosphere, and the wafers W accommodated in each substrate processing chamber 23 are subjected to processing such as etching or film formation.

Further, the substrate processing system 10 includes a controller 25 which controls the operations of individual constituent elements of the substrate processing system 10. The controller 25 includes a CPU, a memory, and the like. The CPU executes processing such as etching or film formation in each substrate processing chamber 23 according to a recipe stored in the memory or the like. Further, the CPU executes the heating of the wafers W in the load lock chambers 17 according to a program stored in the memory or the like.

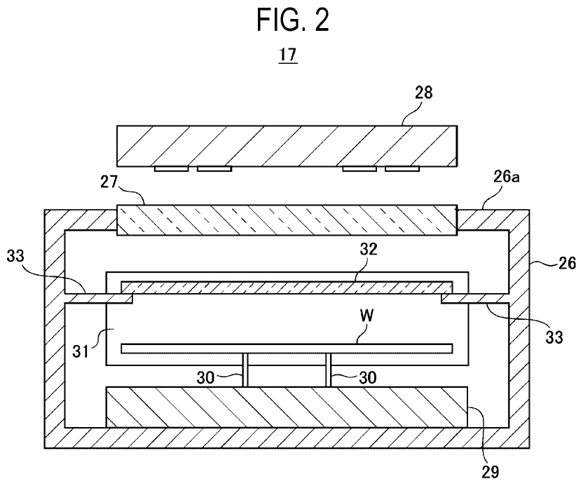

FIG. 2 is a cross-sectional view schematically illustrating a configuration of the load lock chamber 17 in FIG. 1. In FIG. 2, the load lock chamber 17 includes a substantially rectangular parallelepiped accommodation chamber 26 accommodating the wafer W, and a transparent window 27 provided in a ceiling 26a (wall portion) of the accommodation chamber 26. Further, the load lock chamber 17 includes an LED light source 28 (heating light source), which emits LED light (irradiation light), and a stage 29 (cooling source) which cools the wafer W placed thereon.

The stage 29 is arranged at the bottom in an interior of the accommodation chamber 26. The LED light source 28 is arranged outside the accommodation chamber 26, specifically above the ceiling 26a, so as to face the stage 29 via the transparent window 27. Further, the LED light source 28 irradiates the wafer W placed on the stage 29 with the LED light via the transparent window 27. In addition, the LED light source 28 may be attached to the accommodation chamber 26 as long as it faces the stage 29 via the transparent window 27.

Lift pins 30 are arranged on the stage 29 and are configured to freely protrude from an upper surface of the stage 29. Further, a loading/unloading port 31 (loading/unloading port for a substrate exchange), which is open and closed by a gate valve (not illustrated), is provided in a sidewall of the accommodation chamber 26 on a side of the loader chamber 12. When each lift pin 30 lifts up the wafer W from the stage 29, the arm 15 of the transfer robot 13 enters the interior of the accommodation chamber 26, and the pick 16 receives the wafer W thus lifted. Further, when the wafer W is transferred to the interior of the accommodation chamber 26 by the arm 15 of the transfer robot 13, each lift pin 30 protrudes from the stage 29 to receive the wafer W from the pick 16. At this time, the arm 15 of the transfer robot 13 enters the interior of the accommodation chamber 26 via the loading/unloading port 31. In addition, another loading/unloading port (not illustrated), which is open and closed by a gate valve (not illustrated), is also provided in the sidewall of the accommodation chamber 26 that is opposite of the loading/unloading port 31. Then, the arm 21 of the transfer robot 19 enters the interior of the accommodation chamber 26 via another loading/unloading port when each lift pin 30 protrudes from the stage 29, so that the wafer W is delivered between the stage 29 and the transfer robot 19.

Further, the load lock chamber 17 includes a mask member 32 formed as a light-transmitting plate-like member and a rack 33 protruding from the sidewall of the accommodation chamber 26. The mask member 32 is made of one selected from a group consisting of quartz, sapphire, borosilicate glass (heat-resistant glass), a transmissive resin, and the like. The rack 33 is constituted with a plurality of protrusion members protruding in the horizontal direction, and supports peripheral portions of the mask member 32 from below between the transparent window 27 and the stage 29. Thus, the mask member 32 is provided between the transparent window 27 and the wafer W placed on the stage 29. The mask member 32 may have a sufficient size to fully cover the wafer W placed on the stage 29 when viewed from the side of transparent window 27.

The rack 33 is installed at a position where the mask member 32 supported by the rack 33 is exchangeable by moving up and down the arm 15 of the transfer robot 13 which enters the interior of the accommodation chamber 26 via the loading/unloading port 31. When exchanging the mask member 32 with a new one, the arm 15 of the transfer robot 13 enters the interior of the accommodation chamber 26, and further moves upward, so that the pick 16 lifts up and receives the mask member 32 supported by the rack 33. Further, the arm 15 of the transfer robot 13, which holds the new mask member 32 using the pick 16, enters the interior of the accommodation chamber 26, and moves downward, so that the new mask member 32 is delivered to and supported by the rack.

When heating the wafer W in the load lock chamber 17, the wafer W is loaded into the accommodation chamber 26 and placed on the stage 29, and thereafter, the interior of the accommodation chamber 26 is kept in the vacuum atmosphere by the exhaust system. Further, the LED light source 28 irradiates the wafer W with the LED light via the transparent window 27 and the mask member 32. When the LED light is irradiated, the wafer W is overheated so that impurities remaining inside various films formed on the surface of the wafer W are vaporized and released. Subsequently, the vaporized and released impurities are released outward of the accommodation chamber 26 by the exhaust system.

At this time, some of the vaporized and released impurities may move toward the transparent window 27. However, since the mask member 32 is provided between the transparent window 27 and the wafer W placed on the stage 29 in the load lock chamber 17, the movement of the vaporized impurities toward the transparent window 27 is blocked by the mask member 32. Thus, the impurities are less likely to reach the transparent window 27. This makes it possible to suppress the impurities from adhering to the transparent window 27, thus preventing a decrease in the transmittance of the transparent window 27. Accordingly, the heating efficiency of the wafer W by the LED light from the LED light source 28 may be prevented from being reduced.

On the other hand, since the mask member 32 blocks the vaporized impurities, the impurities adhere to the mask member 32, which decreases the transmittance of the mask member 32. As a result, the heating efficiency of the wafer W by the LED light from the LED light source 28 may be reduced. However, as described above, the mask member 32 may be easily exchanged with a new one by the transfer robot 13. Therefore, by exchanging the mask member 32 with the new one at the timing at which a certain amount of impurities have adhered to the mask member 32 and therefore the transmittance of the mask member 32 is reduced, the transmittance of the mask member 32 may be restored. Accordingly, the heating efficiency of the wafer W by the LED light from the LED light source 28 may be prevented from being reduced.

In addition, the heating of the wafer W in the load lock chamber 17 may be performed either before the wafer W is subjected to various types of processing in each substrate processing chamber 23 or after the wafer W has been subjected to various types of processing in each substrate processing chamber 23.

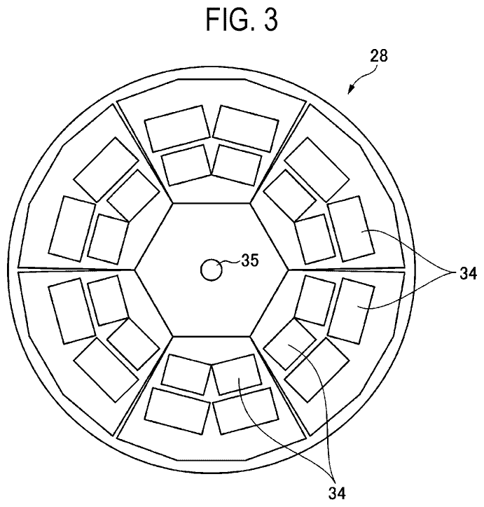

FIG. 3 is a diagram illustrating the LED light source 28 in FIG. 2 as viewed from below. In FIG. 3, the LED light source 28 is substantially disk-shaped as a whole. A plurality of light source chips 34 is arranged concentrically and radially on a lower surface of the LED light source 28 facing the transparent window 27 (all rectangles in the drawing represent the light source chips 34). Further, a single radiation thermometer 35 that is oriented downward is arranged at the center of the lower surface. In addition, a plurality of radiation thermometers 35 may be provided. In this case, the radiation thermometers 35 are also arranged on peripheral portions of the lower surface, in addition to the center of the lower surface.

Light absorptivity of silicon (Si) constituting the wafer W sharply deteriorates when a wavelength of light becomes approximately 1000 nm or more. The wavelength of the LED light emitted from each light source chip 34 is 400 nm or less, for example, 395 nm. Further, since the wavelength of the LED light does not vary, the LED light with a wavelength of approximately 1,000 nm or more is not emitted from each light source chip 34. As a result, the deterioration in the light absorptivity of the wafer W due to the wavelength of the LED light does not occur, ensuring that the heating efficiency of the wafer W by LED light is not reduced.

Further, the radiation thermometer 35 measures a temperature of the wafer W by measuring light emitted from the wafer, which has a wavelength of approximately 950 nm (hereinafter referred to as “temperature measurement light”) in terms of a temperature value. In this case, since the wavelength of the LED light emitted from each light source chip 34 is 400 nm or less, the radiation thermometer 35 does not erroneously measure the LED light emitted from each light source chip 34 in terms of a temperature value. This makes it difficult for the radiation thermometer 35 to erroneously measure the LED light.

Further, LED light with a wavelength of 400 nm or less has characteristics similar to those of ultraviolet light, and has high light energy. This may facilitate decomposition of the substances through the light energy itself. In particular, the decomposition of the impurities adhered to the surface of the wafer W may be facilitated. In addition, LED has a significantly low standby power. Thus, the LED light source 28 consumes minimal power when the wafer W is not being heated, which contributes to energy-saving effects.

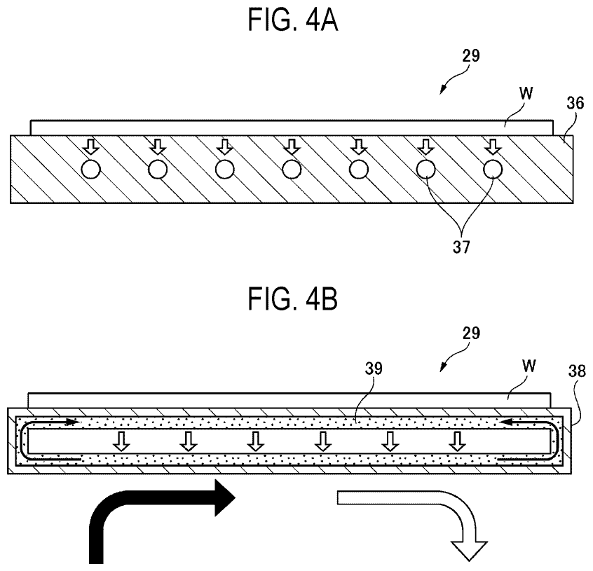

FIGS. 4A and 4B are cross-sectional views schematically illustrating the configuration of the stage 29 in FIG. 2. The stage 29 in the present embodiment has a function of cooling the wafer W. For example, the stage 29 may be constituted with a main body 36, which is formed as a plate-like member made of a metal with high thermal conductivity, for example, an aluminum plate-like member. A coolant flow path 37 may be formed in the main body 36, and a coolant may flow through the coolant flow path 37 (FIG. 4A). The coolant flowing through the coolant flow path 37 may be, for example, water, ethanol (C₂H₆O), a mixture of water and a saturated gas, or a mixture of ethanol and the saturated gas. When the coolant flows through the coolant flow path 37, heat is transferred from the heated wafer W to the coolant flow path 37 (see the white arrows in the drawing), so as to cool the wafer W.

Further, the stage 29 may be constituted with a vapor chamber (FIG. 4B). In this case, the main body of the stage 29 is constituted with a heat exchange chamber 38 whose interior is hollow. An inner surface of the heat exchange chamber 38 is coated with a capillary structure 39, and an operating fluid functioning as the coolant is injected to the interior of the heat exchange chamber 38. Here, the operating fluid, filled into the capillary structure 39 at an upper portion of the heat exchange chamber 38, i.e., directly below the wafer W, vaporizes by the heat transferred from the heated wafer W. By cooling of vaporization heat at this time, the operating fluid draws heat from the wafer W. Further, the vaporized operating fluid flows downward in the interior of the heat exchange chamber 38 (see the white arrows in the drawing), and reaches the capillary structure 39 at a lower portion of the heat exchange chamber 38. At this time, the heat of the operating fluid is drawn by a heat exchange mechanism in contact with a lower surface of the stage 29, so that the operating fluid is re-liquefied. The re-liquefied operating fluid flows in the interior of the capillary structure 39 and circulates to the upper portion of the heat exchange chamber 38 (see the black arrows in the drawing), where the operating fluid vaporizes again by heat transfer from the wafer W. By repeating a cycle including the vaporization and the liquefaction of the operating fluid, the wafer W may be continuously cooled by the stage 29. Further, since the operating fluid is distributed and vaporizes substantially uniformly in the capillary structure 39 at the upper portion of the heat exchange chamber 38, the stage 29 is cooled substantially uniformly, so that the wafer W placed on the stage 29 may be cooled with in-plane uniformity. In addition, the flow of the coolant in the heat exchange mechanism in contact with the lower surface of the stage 29 is indicated by thick arrows, the flow of a low-temperature coolant is indicated by the black thick arrow and the flow of a high-temperature coolant is indicated by the white thick arrow. Further, in general, gas-based heat exchange is more efficient than heat transfer in a metal. Therefore, by constituting the stage 29 with the vapor chamber, the wafer W may be cooled more quickly, which makes it possible to quickly complete the heating of the wafer W in the load lock chamber 17. This improves throughput.

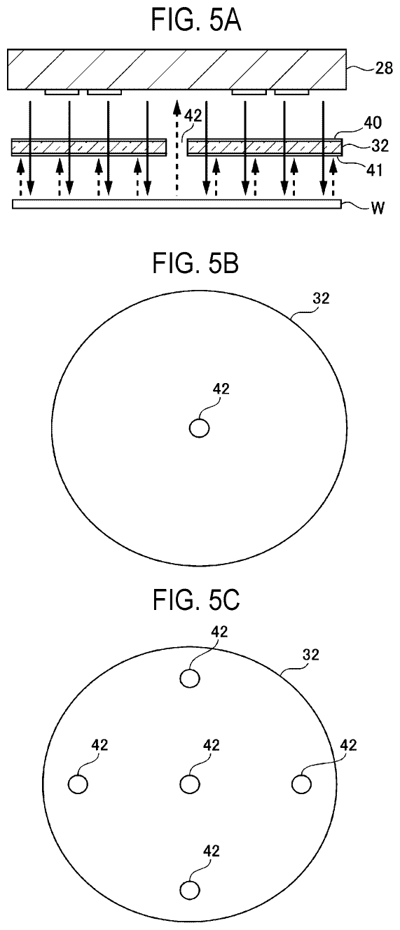

FIGS. 5A to 5C are diagrams illustrating the configuration of the mask member 32 in FIG. 2. As schematically illustrated in FIG. 5A, the mask member 32 is provided between the LED light source 28 and the wafer W. Accordingly, the mask member 32 is irradiated with the LED light (indicated by solid arrows) from the LED light source 28, and is irradiated with infrared light (indicated by dashed arrows) emitted from the heated wafer W.

When an upper surface of the mask member 32 facing the LED light source 28 reflects the LED light, an amount of the LED light transmitted through the mask member 32 may be decreased by an amount of reflection and therefore, which may result in a decrease in the heating efficiency of the wafer W by the LED light. In one embodiment, an anti-reflection film 40 that prevents the reflection of the LED light is formed on the upper surface of the mask member 32 facing the LED light source 28. The anti-reflection film 40 is made of, for example, magnesium fluoride (MgF₂), titanium (IV) oxide (TiO₂), zirconia (ZrO₂), or aluminum oxide (Al₂O₃), and prevents the reflection of the LED light. This makes it possible to prevent the decrease in the amount of the LED light transmitted through the mask member 32.

Further, when the infrared light emitted from the wafer W transmits through the mask member 32, the LED light source 28 may be heated by the infrared light, which may result in a change in the wavelength of the LED light from each light source chip 34. In one embodiment, a transmission control film 41 that reflects the infrared light to control the transmission of the infrared light is formed on the lower surface of the mask member 32 facing the wafer W. The transmission control film 41 is made of one selected from a group consisting of gold (Au), silver (Ag), titanium nitride (TiN), tungsten (W) and ruthenium (Ru), and controls the transmission of the infrared light to prevent the infrared light from reaching the LED light source 28. This makes it possible to prevent the LED light source 28 from being heated by the infrared light. Further, as described above, the wavelength of the LED light irradiated from the LED light source 28 is 400 nm or less. Gold reflects only light with a wavelength of 800 nm or more and silver reflects only light with a wavelength of 450 nm or more. Thus, the transmission of the LED light is not suppressed. Therefore, the transmission control film 41 may be made of gold or silver from the viewpoint of suppressing the decrease in the heating efficiency of the wafer W by LED light. In addition, in a case in which the anti-reflection film 40 is not formed on the upper surface of the mask member 32, the transmission control film 41 may be formed on the upper surface of the mask member 32.

Meanwhile, the radiation thermometer 35 of the LED light source 28 measures the temperature of the wafer W by measuring the temperature measurement light emitted from the wafer W in terms of a temperature value. Here, in the case in which the transmission control film 41 is made of gold or silver, the transmission control film 41 may reflect the temperature measurement light with a wavelength of approximately 950 nm, which may hinder measuring the temperature of the wafer W by the radiation thermometer 35. In one embodiment, a through-hole 42, which is open to face the radiation thermometer 35, is formed in the mask member 32. As described above, the radiation thermometer 35 is arranged at the center of the lower surface of the LED light source 28. Thus, the through-hole 42 is formed at the center of the mask member 32, and the radiation thermometer 35 faces the wafer W via the through-hole 42 (FIG. 5B). In this way, the temperature measurement light emitted from the wafer W passes through the through-hole 42 and reaches the radiation thermometer 35. Thus, it is possible to prevent the transmission control film 41 from interfering with the measurement of the temperature of the wafer W by the radiation thermometer 35. In addition, in a case in which a plurality of radiation thermometers 35 is arranged on the peripheral portions of the lower surface of the LED light source 28, a plurality of through-holes 42 may be formed in the mask member 32 to face the respective radiation thermometers 35 (FIG. 5C).

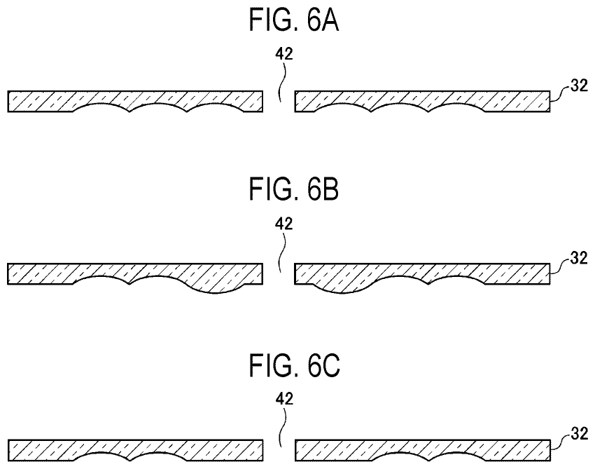

Further, as described above, the plurality of light source chips 34 is arranged on the lower surface of the LED light source 28 facing the transparent window 27 (the wafer W). In an ideal case, the respective light source chips 34 may be arranged such that the wafer W may be heated with an in-plane uniformity by the LED light from the respective light source chips 34. However, according to a shape of each light source chip 34 and a layout of wirings with respect to each light source chip 34, the respective light source chips 34 may be limitedly arranged. This makes it difficult to implement such an ideal arrangement. In one embodiment, a lens function may be provided to adjust the distribution of the LED light with respect to the mask member 32. Specifically, a plurality of convex lenses or a plurality of concave lenses may be formed on the lower surface of the mask member 32 facing the wafer W so that the LED light transmitting through the mask member 32 heats the wafer W with an in-plane uniformity. The arrangement of the convex lenses or concave lenses on the lower surface of the mask member 32 may be changed according to the arrangement of the light source chips 34 in the LED light source 28 (see the cross-sectional views of the mask member 32 in FIGS. 6A to 6C).

According to a technology of the present disclosure, it is possible to suppress a decrease in heating efficiency of a substrate by LED light. The preferred embodiments of the present disclosure have been described above, but the present disclosure is not limited to these embodiments, and various modifications and changes can be made within the scope of the disclosure.

For example, in the present embodiment, each load lock chamber 17 was used as a substrate heating apparatus, but the substrate heating apparatus may be configured as an independent substrate heating module, and the substrate heating module may be connected to the loader chamber 12 or the substrate transfer chamber 18.

Further, in the present embodiment, a wafer, which serves as a substrate, was heated in the load lock chamber 17, but a different type of substrate other than the wafer, for example, a glass substrate, may be heated in the load lock chamber 17. Furthermore, even though an LED light source 28 was used as a heating light source in the present embodiment, a halogen light source that emits halogen light toward the wafer W may be used as a heating light source.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate heating apparatus comprising:
an accommodation chamber configured to accommodate a substrate;
a transparent window provided on a wall portion of the accommodation chamber to face the substrate;
a heating light source configured to irradiate the substrate with an irradiation light via the transparent window and configured to heat the substrate; and
a light-transmitting mask member provided between the transparent window and the substrate.

2. The substrate heating apparatus of claim 1, wherein the light-transmitting mask member is made of one selected from a group consisting of quartz, borosilicate glass, sapphire, and a transmissive resin.

3. The substrate heating apparatus of claim 1, wherein the light-transmitting mask member has a lens function of adjusting a distribution of the irradiation light.

4. The substrate heating apparatus of claim 1, wherein the light-transmitting mask member is formed as a plate-like member, and includes an anti-reflection film formed on a surface facing the transparent window.

5. The substrate heating apparatus of claim 4, wherein the anti-reflection film is made of one selected from a group consisting of magnesium fluoride (MgF₂), titanium (IV) oxide (TiO₂), zirconia (ZrO₂), and aluminum oxide (Al₂O₃).

6. The substrate heating apparatus of claim 1, wherein the light-transmitting mask member is formed as a plate-like member, and includes a transmission control film formed on a surface facing the substrate.

7. The substrate heating apparatus of claim 6, wherein the transmission control film is made of one selected from a group consisting of gold (Au), silver (Ag), titanium nitride (TiN), tungsten (W), and ruthenium (Ru).

8. The substrate heating apparatus of claim 1, wherein the heating light source includes a radiation thermometer,
wherein the light-transmitting mask member has a through-hole open to face the radiation thermometer, and
wherein the radiation thermometer faces the substrate via the through-hole.

9. The substrate heating apparatus of claim 1, further comprising a rack configured to support the light-transmitting mask member between the transparent window and the substrate.

10. The substrate heating apparatus of claim 9, wherein the rack is installed at a position where the light-transmitting mask member supported by the rack is exchangeable by a substrate transfer mechanism which enters an interior of the accommodation chamber via a loading/unloading port for a substrate exchange in the accommodation chamber.

11. The substrate heating apparatus of claim 1, further comprising a cooling source configured to place the substrate thereon and cool the substrate.

12. The substrate heating apparatus of claim 11, wherein the cooling source is constituted with one of a plate-like member incorporating a coolant flow path or a vapor chamber.

13. The substrate heating apparatus of claim 12, wherein a coolant flowing through the coolant flow path or an operating fluid used in the vapor chamber is water, ethanol (C₂H₆O), a mixture of the water and a saturated gas, or a mixture of ethanol and the saturated gas.

14. The substrate heating apparatus of claim 1, wherein the irradiation light is LED light with a wavelength of 400 nm or less.

15. A substrate heating method comprising:
accommodating a substrate in an accommodation chamber;
positioning the substrate to face a transparent window provided on a wall portion of the accommodation chamber;
providing a light-transmitting mask member between the transparent window and the substrate; and
irradiating the substrate with an irradiation light from a heating light source via the transparent window to heat the substrate.
